(19) United States
(12) Patent Application Publication
(10) Pub. No.: US 2026/0018475 A1
(43) Pub. Date: Jan. 15, 2026

(54) SEMICONDUCTOR PACKAGE

(71) Applicant: SAMSUNG ELECTRONICS CO., LTD., Suwon-si (KR)

(72) Inventors: Eunhye Lee, Suwon-si (KR); Dongok Kwak, Suwon-si (KR)

(73) Assignee: SAMSUNG ELECTRONICS CO., LTD., Suwon-si (KR)

(21) Appl. No.: 19/169,688

(22) Filed: Apr. 3, 2025

(30) Foreign Application Priority Data
Jul. 11, 2024 (KR) 10-2024-0091572

(51) Int. Cl. H01L 23/13; H01L 23/00; H01L 23/538; H01L 25/18; H10B 80/00; H10D 80/30

(52) U.S. Cl. CPC H01L 23/13; H01L 24/32; H01L 25/18; H01L 23/5383; H01L 23/5386; H01L 24/16; H01L 24/48; H01L 24/73; H01L 24/83; H01L 2224/16227; H01L 2224/16238; H01L 2224/3201; H01L 2224/32054; H01L 2224/32058; H01L 2224/32059; H01L 2224/3207; H01L 2224/32145; H01L 2224/32225; H01L 2224/48147; H01L 2224/48227; H01L 2224/73204; H01L 2224/73215; H01L 2224/73253; H01L 2224/73265; H01L 2224/83203; H01L 2225/06506; H01L 2225/0651; H01L 2225/06517; H01L 2225/06524; H01L 2225/06562; H01L 2924/1431; H01L 2924/1436; H10B 80/00; H10D 80/30

(57) ABSTRACT

A semiconductor package includes a package substrate having an upper surface, a lower surface opposite to the upper surface, and a receiving groove that extends from the upper surface, toward the lower surface, by a predetermined depth; a first semiconductor chip in the receiving groove and protruding from the upper surface of the package substrate to have a predetermined height from the upper surface of the package substrate; an underfill member in the receiving groove and between the first semiconductor chip and an inner surface of the receiving groove; a plurality of second semiconductor chips sequentially stacked on the first semiconductor chip; and a molding member on the package substrate and covering the first semiconductor chip and the plurality of second semiconductor chips.

### CROSS-REFERENCE TO RELATED APPLICATION

This application claims priority under 35 U.S.C. § 119 to Korean Patent Application No. 10-2024-0091572, filed on Jul. 11, 2024, in the Korean Intellectual Property Office, the disclosure of which is incorporated by reference herein in its entirety.

### BACKGROUND

### 1. Field

The disclosure relates to a semiconductor package and a method of manufacturing the semiconductor package, and more particularly, to a semiconductor package including different types of chips stacked on a package substrate and a method for manufacturing the same.

### 2. Description of Related Art

In a multi-chip package (MCP), memory chips may be stacked on a controller chip of a relatively small size. At this time, the controller chip may be mounted on a package substrate by a flip chip bonding method. In this case, an underfill material filling a space between the controller chip and the package substrate may overflow, causing a defect. Further, because an additional dam structure is formed in order to prevent the defect due to such overflow, there is a problem in that the degree of freedom for chip arrangement is reduced.

### SUMMARY

Example embodiments provide a semiconductor package having a reduced package size and having a structure that may improve the degree of freedom for chip arrangement.

According to an aspect of one or more example embodiments, a semiconductor package includes: a package substrate including an upper surface, a lower surface opposite to the upper surface, and a receiving groove that extends from the upper surface, toward the lower surface, by a predetermined depth; a first semiconductor chip in the receiving groove and protruding from the upper surface of the package substrate to have a predetermined height from the upper surface of the package substrate; an underfill member in the receiving groove and between the first semiconductor chip and an inner surface of the receiving groove; a plurality of second semiconductor chips sequentially stacked on the first semiconductor chip; and a molding member on the package substrate and covering the first semiconductor chip and the plurality of second semiconductor chips.

According to an aspect of one or more example embodiments, a semiconductor package includes: a package substrate including a receiving groove that extends from an upper surface of the package substrate, toward a lower surface of the package substrate, by a predetermined depth; a first semiconductor chip in the receiving groove and protruding from the upper surface of the package substrate to have a first predetermined height from the upper surface of the package substrate; at least one semiconductor element in the receiving groove of the package substrate and protruding from the upper surface of the package substrate to have a second predetermined height from the upper surface of the package substrate; an underfill member in the receiving groove, the underfill member including: a first covering portion between the first semiconductor chip and a bottom surface of the receiving groove, and a second covering portion between the first semiconductor chip and a sidewall of the receiving groove; a plurality of second semiconductor chips sequentially stacked on the first semiconductor chip by adhesive films; and a molding member covering the first semiconductor chip and the plurality of second semiconductor chips, wherein the molding member is on the package substrate, and the underfill member further includes a third covering portion that protrudes from the receiving groove, covers a side surface of the first semiconductor chip, and covers a portion of the upper surface of the package substrate extending along a perimeter of the receiving groove.

According to an aspect of one or more example embodiments, a semiconductor package includes: a package substrate including a receiving groove that extends from an upper surface of the package substrate, toward a lower surface of the package substrate, by a predetermined depth, wherein the package substrate includes: first substrate pads on a bottom surface of the receiving groove; and second substrate pads on the upper surface of the package substrate; a first semiconductor chip in the receiving groove and protruding from the upper surface of the package substrate to have a predetermined height from the upper surface of the package substrate, wherein the first semiconductor chip is mounted on the first substrate pads using conductive bumps that are provided on first chip pads of the first semiconductor chip; an underfill member in the receiving groove, the under fill member including: a first covering portion between the first semiconductor chip and the bottom surface of the receiving groove; and a second covering portion between the first semiconductor chip and a sidewall of the receiving groove; a plurality of second semiconductor chips sequentially stacked on the first semiconductor chip using adhesive films, wherein the plurality of second semiconductor chips include second chip pads that are electrically connected to the second substrate pads by bonding wires; and a molding member on the package substrate and covering the first semiconductor chip and the plurality of second semiconductor chips, wherein the underfill member further includes a third covering portion that protrudes from the receiving groove, covers a side surface of the first semiconductor chip, and covers a portion of the upper surface of the package substrate extending along a perimeter of the receiving groove.

According to one or more embodiments, because a portion of the first semiconductor chip used as the support structure is inserted into the receiving groove of the package substrate, a bond line thickness may be reduced and the overall package thickness may be reduced. In addition, because the underfill member having fluidity is formed while filling the inside of the receiving groove, overflow of the underfill member may be prevented, thereby reducing defects, and because there is no need to form a separate dam structure for receiving the underfill member, the degree of freedom for chip arrangement may be increased.

### BRIEF DESCRIPTION OF THE DRAWINGS

The above and other aspects and features will be more apparent from the following detailed description taken in conjunction with the accompanying drawings, in which:

FIG. 1 is a plan view illustrating a semiconductor package in accordance with one or more example embodiments;

FIG. 2 is a cross-sectional view taken along the line A1-A1′ in FIG. 1, according to one or more example embodiments;

FIG. 3 is a cross-sectional view taken along the line B1-B1′ in FIG. 1, according to one or more example embodiments;

FIG. 4 is an enlarged cross-sectional view illustrating portion ‘C1’ in FIG. 2, according to one or more example embodiments;

FIGS. 5, 6, 7, 8, 9, 10, 11, 12, 13, 14, 15, 16, 17, 18 and 19 are views illustrating a method of manufacturing a semiconductor package in accordance with one or more example embodiments; and

FIG. 20 is an enlarged cross-sectional view illustrating a portion of a semiconductor package in accordance with one or more example embodiments.

### DETAILED DESCRIPTION

Hereinafter, example embodiments will be explained in detail with reference to the accompanying drawings.

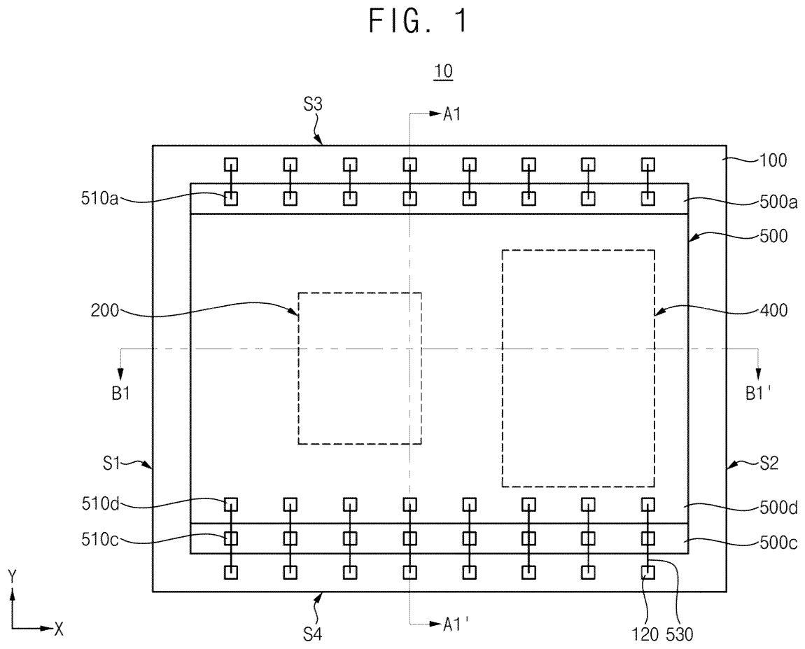

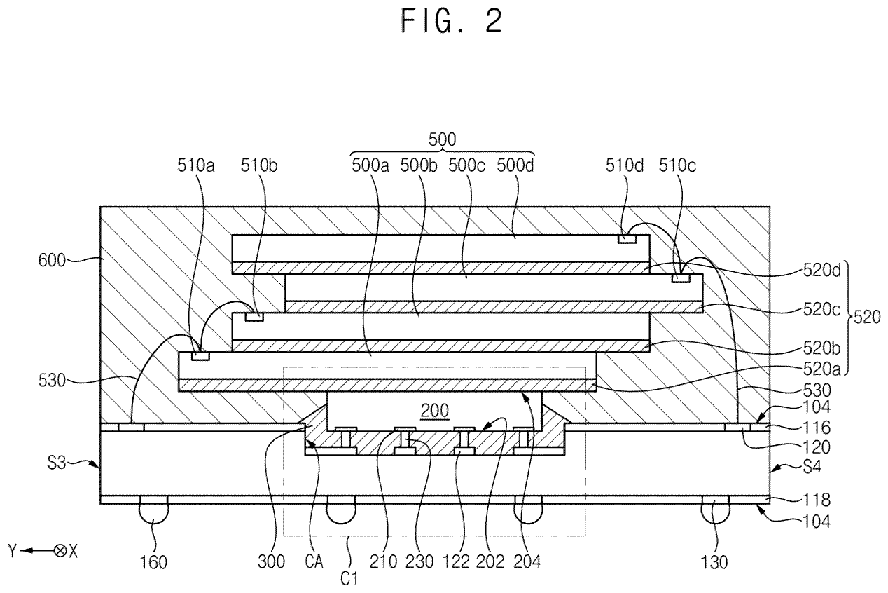

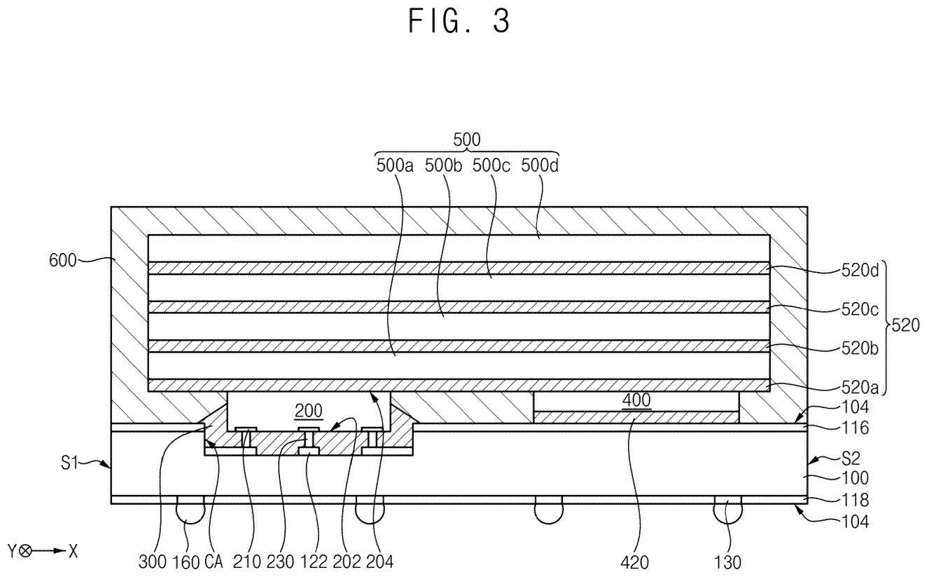

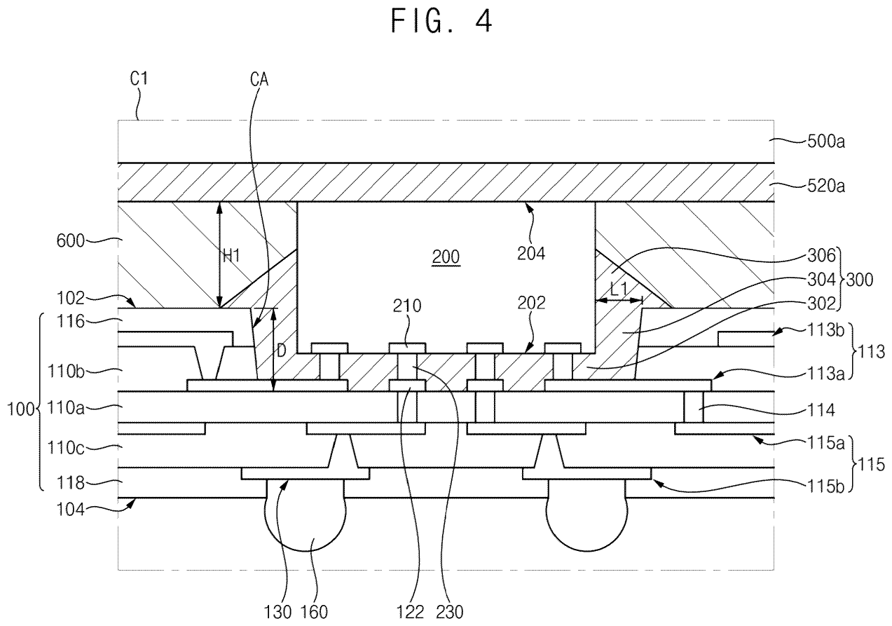

FIG. 1 is a plan view illustrating a semiconductor package in accordance with one or more example embodiments. FIG. 2 is a cross-sectional view taken along the line A1-A1′ in FIG. 1, according to one or more example embodiments. FIG. 3 is a cross-sectional view taken along the line B1-B1′ in FIG. 1, according to one or more example embodiments. FIG. 4 is an enlarged cross-sectional view illustrating portion ‘C1’ in FIG. 2, according to one or more example embodiments. FIG. 1 is a plan view illustrating the semiconductor package, wherein a molding member in FIGS. 2 and 3 is omitted, according to one or more example embodiments.

Referring to FIGS. 1, 2, 3 and 4, a semiconductor package 10 may include a package substrate 100, a first semiconductor chip 200, an underfill member 300, a plurality of second semiconductor chips 500, and a molding member 600. The semiconductor package 10 may further include a support spacer, i.e., spacer chip 400. The semiconductor package 10 may further include conductive connection members, such as conductive bumps 230 and bonding wires 530 that electrically connect the first semiconductor chip 200 and the plurality of second semiconductor chips 500 to the package substrate 100. In addition, the semiconductor package 10 may further include external connection members 160.

In addition, the semiconductor package 10 may be a multi-chip package (MCP) including different types of semiconductor chips. The semiconductor package 10 may be a System In Package (SIP) including a plurality of semiconductor chips stacked or arranged in one package to perform all or most of the functions of an electronic system.

In one or more example embodiments, the package substrate 100 may be a substrate having an upper surface 102 and a lower surface 104 opposite to each other. For example, the package substrate 100 may include a printed circuit board (PCB), such as a core multilayer substrate. Alternatively, the package substrate 100 may include a coreless substrate. The package substrate 100 may include internal wirings as channels for electrical connection with the first semiconductor chip 200 and the second semiconductor chips 500. The package substrate 100 may include internal wirings as channels for electrical connection with the first semiconductor chip 200 and the second semiconductor chips 500.

The package substrate 100 may include a first side portion S1 and a second side portion S2 extending in a direction parallel to a second direction (Y direction) and facing each other. The package substrate 100 may include a third side portion S3 and a fourth side portion S4 extending in a direction parallel to a first direction (X direction) perpendicular to the second direction and facing each other.

The package substrate 100 may have a receiving groove CA having a predetermined depth D from the upper surface 102. When viewed in a plan view, the receiving groove CA may have a shape corresponding to a shape of the first semiconductor chip 200. The receiving groove CA may have an approximately rectangular shape. The receiving groove CA may be arranged adjacent to the first side portion S1.

For example, the depth D of the receiving groove CA may be at least 10 μm. The depth D of the receiving groove CA may be within a range of 10 μm to 150 μm. The depth, position, planar area, etc. of the receiving groove CA may be determined in consideration of a thickness, planar area, etc. of the first semiconductor chip 200 placed in the receiving groove, a thickness of the underfill member 300, etc.

The receiving groove CA may have a chip mounting region in a center region where the first semiconductor chip 200 is mounted. The chip mounting region may have a rectangular shape corresponding to the shape of the first semiconductor chip 200.

The package substrate 100 may have first substrate pads 122 for electrical connection with the first semiconductor chip 200 and second substrate pads 120 for electrical connection with the second semiconductor chips 500. The first substrate pads 122 may be provided in the chip mounting region on a bottom surface of the receiving groove CA. The first substrate pads 122 may be arranged in an array form within the chip mounting region. The second substrate pads 120 may be provided along the third and fourth side portions S3, S4 on the upper surface 102 of the package substrate 100. The first substrate pads 122 and the second substrate pads 120 may be connected to the wirings, respectively. The wirings may extend from the upper surface 102 or within the package substrate 100. For example, at least a portion of the wirings may be used as a landing pad for the substrate pad. Although only a few substrate pads are illustrated in the figures, it will be understood that the number, shape, and arrangement of the substrate pads are provided by way of example, and one or more example embodiments are not limited thereto.

As illustrated in FIG. 4, in one or more example embodiments, the package substrate 100 may include a core multilayer substrate. For example, the package substrate 100 may include a core layer 110a, an upper insulating layer 110b on an upper surface of the core layer 110a, and a lower insulating layer 110c on a lower surface of the core layer 110a. The package substrate 100 may further include a plurality of through vias 114 penetrating the core layer 110a, a first upper circuit layer 113a on the upper surface of the core layer 110a, a second upper circuit layer 113b provided on the upper insulating layer 110b, a first lower circuit layer 115a on the lower surface of the core layer 110a, and a second lower circuit layer 115b provided on the lower insulating layer 110c. Protective layers 116 and 118 such as solder resist layers, may be formed on outermost surfaces of the circuit layers. An upper protective layer 116 may cover the entire upper surface of the insulating layers except for the second substrate pads 120. A lower protective layer 118 may cover the entire lower surface of the insulating layers except for the lower substrate pads 130.

Each of the circuit layers may include a wiring pattern. Each of the wiring patterns may include a pad, a trace, a via, etc. An upper surface of the upper protective layer 116 may be provided as the upper surface 102 of the package substrate 100, and a lower surface of the lower protective layer 118 may be provided as the lower surface 104 of the package substrate 100. At least a portion of a pad of the second upper circuit layer 113b may be provided as the second substrate pad 120, and at least a portion of a pad of the second lower circuit layer 115b may be provided as the lower substrate pad 130.

The package substrate 100 may be provided with the receiving groove CA having the predetermined depth D from the upper surface 102. For example, the receiving groove CA may be formed by an etching process, a laser drill process, etc. The receiving groove CA may have the predetermined depth D from the upper surface 102 of the package substrate 100 and may expose portions (e.g., pad portions) 120 of the circuit layer 113a. The exposed pad portions may be provided as the first substrate pads 122. As described below, portions of the wirings of the first upper circuit layer 113a exposed from the receiving groove CA may be pad patterns on which conductive bumps 230 formed on the first semiconductor chip 200 are respectively disposed by a flip chip bonding method. A plurality of the first substrate pads 122 may be arranged in an array form on the bottom surface of the receiving groove CA.

In one or more example embodiments, the first semiconductor chip 200 may be placed in the receiving groove CA of the package substrate 100. The first semiconductor chip 200 may be mounted in the receiving groove CA of the package substrate 100 by a flip chip bonding method.

The first semiconductor chip 200 may be arranged such that a front surface 202, i.e., an active surface, on which the first chip pads 210 are formed, faces the bottom surface of the receiving groove CA of the package substrate 100. The first semiconductor chip 200 may be electrically connected to the first substrate pads 122 of the package substrate 100 via conductive bumps 230. The conductive bumps 230 formed on the first chip pads 210 of the first semiconductor chip 200 may be bonded to the first substrate pads 122 on the bottom surface of the receiving groove CA. The first semiconductor chip 200 may have a rectangular shape with four sides when viewed in a plan view.

The first semiconductor chip 200 may be a logic chip including a logic circuit. The logic chip may be a controller that controls memory chips. The first semiconductor chip may be a processor chip such as an application-specific integrated circuit (ASIC) or an application processor AP as a host such as a central processing unit (CPU), graphics processing unit (GPU), or system-on-a-chip (SOC).

For example, a thickness of the first semiconductor chip 200 may be within a range of 30 μm to 100 μm. A height H1 of the first semiconductor chip 200 from the upper surface 102 of the package substrate 100 may be within a range of 30 μm to 150 μm.

As illustrated in FIG. 4, the first semiconductor chip 200 may be mounted on the first substrate pads 122 of the package substrate 100 using the conductive bumps 230. The conductive bumps 230 may be bonded to the first chip pads 210 of the first semiconductor chip 200 and the first substrate pads 122. Accordingly, the first chip pads 210 of the first semiconductor chip 200 may be electrically connected to the first substrate pads 122 of the package substrate 100 by the conductive bumps 230 as conductive connection members. For example, each of the conductive bumps 230 may include a pillar bump and a solder bump formed on the pillar bump. Alternatively, each of the conductive bumps 230 may include a solder bump.

The first semiconductor chip 200 may protrude from the package substrate 100 by a predetermined height H1. The first semiconductor chip 200 may be used as a support structure to support at least a portion of the second semiconductor chips 500 positioned above the upper surface 102 of the package substrate 100. The height H1 of the first semiconductor chip 200 protruding from the package substrate 100 may be determined in consideration of sizes of fillers of the molding member 600, a height of the second semiconductor chips 500 from the upper surface 102 of the package substrate 100, etc.

In one or more example embodiments, the underfill member 300 may fill the receiving groove CA of the package substrate 100 and may fill a space between the first semiconductor chip 200 and an inner surface of the receiving groove CA. For example, the underfill member 300 may include a thermosetting resin such as an epoxy resin. The underfill member 300 may include a first covering portion 302 that fills a space between the first semiconductor chip 200 and the bottom surface of the receiving groove CA and a second covering portion 304 that fills a space between the first semiconductor chip 200 and a sidewall of the receiving groove CA. For example, a distance L1 between the first semiconductor chip 200 and the sidewall of the receiving groove CA may be within a range of 40 μm to 100 μm.

In addition, the underfill member 300 may further include a third covering portion 306 that covers a side surface of the first semiconductor chip 200 protruding from the receiving groove CA and a portion of the upper surface 102 extending along a perimeter of the receiving groove CA. The third covering portion 306 may cover at least a portion of the side surface of the first semiconductor chip 200. Accordingly, an upper surface 204, i.e., an inactive surface of the first semiconductor chip 200 may be exposed from the underfill member 300.

In one or more example embodiments, the support spacer 400 may be arranged on the upper surface 102 of the package substrate 100 to be spaced apart from the first semiconductor chip 200. The support spacer 400 may be attached to the upper surface 102 of the package substrate 100 by an adhesive film 420. The support spacer 400 may be arranged adjacent to the second side portion S2. The support spacer 400 may be formed by cutting a silicon wafer W by a sawing process, and then may be attached to the upper surface 102 of the package substrate 100 by using the adhesive film 420 in a die attach process.

A height of the support spacer 400 from the package substrate 100 may be determined in consideration of the height H1 of the first semiconductor chip 200 protruding from the upper surface 102 of the package substrate 100. The height of the support spacer 400 from the package substrate 100 may be equal to or greater than the height H1 of the first semiconductor chip 200 from the package substrate 100.

In one or more example embodiments, the plurality of second semiconductor chips 500 may be supported and mounted on the first semiconductor chip 200 and the support spacer 400. The plurality of second semiconductor chips 500 may be attached to the first semiconductor chip 200 using adhesive films 520. A lowermost second semiconductor chip 500a among the plurality of second semiconductor chips 500 may be attached to an upper surface of the first semiconductor chip 200 using a first adhesive film 520a. Remaining chips 500b, 500c, 500d of the plurality of second semiconductor chips 500 may be sequentially attached to the lowermost second semiconductor chips 500a using second adhesive films 520b, 520c and 520d.

The second semiconductor chips 500 may include a memory chip including a memory circuit. For example, the second semiconductor chips 500 may include volatile memory devices such as static random access memory (SRAM) devices, dynamic random access memory (DRAM) devices, etc., and non-volatile memory devices such as flash memory devices, phase-change random access memory (PRAM) devices, magneto-resistive random access memory (MRAM) devices, resistive random access memory (RRAM) devices, etc. In one or more example embodiments, the second semiconductor chips 500 may include DRAM devices.

The lowermost second semiconductor chip 500a may be attached to the first semiconductor chip 200 and the support spacer 400 by using the first adhesive film 520a such as a die attach film (DAF) in a die attach process.

The lowermost second semiconductor chip 500a may be arranged such that a backside surface, i.e., an inactive surface opposite to a front surface on second chip pads 510a are formed, faces the package substrate 100. The second semiconductor chip 500a may have a rectangular shape with four sides when viewed in plan view.

The remaining chips 500b, 500c, 500d, among the plurality of second semiconductor chips 500, may be sequentially attached to the lowermost second semiconductor chip 500a by the second adhesive films 520b. The second semiconductor chips 500b, 500b, 500c may be sequentially attached to the lowermost second semiconductor chip 500a using the second adhesive films 520b such as a die attach film (DAF) in a die attach process. A thickness of each of the second adhesive films 520b, 520c, 520d may be less than a thickness of the first adhesive film 520a. The thickness of each of the second adhesive films 520b, 520c, 520d may be within a range of 10 μm to 20 μm.

A planar area of the second semiconductor chips 500 may be greater than a planar area of the first semiconductor chip. The plurality of second semiconductor chips 500a, 500b, 500c, and 500d may be aligned to overlap each other. The plurality of second semiconductor chips 500a, 500b, 500c, and 500d may be sequentially offset aligned from each other.

It will be understood that the number, size, arrangement, etc. of the second semiconductor chips 500 are provided as examples, and one or more example embodiments are not limited thereto. Additionally, although only a few second chip pads are illustrated in the figures, it will be understood that the structure, shapes and arrangements of the second chip pads are provided by way of example and that one or more example embodiments are not limited thereto.

The second semiconductor chips 500 may be electrically connected to the package substrate 100 by conductive connection members such as bonding wires 530. Specifically, the second chip pads 510 of the second semiconductor chips 500 may be electrically connected to the second substrate pads 120 on the upper surface 102 of the package substrate 100 by the bonding wires 530.

In one or more example embodiments, the molding member 600 may cover the first semiconductor chip 200, the second semiconductor chips 500, the support spacer 400 and the conductive bumps 230 and the bonding wires 530 on the upper surface 102 of the package substrate 100. The molding member 600 may include a thermosetting resin, for example, an epoxy mold compound (EMC). The molding member 600 may include fillers and epoxy resin that acts as a binder for the fillers.

In one or more example embodiments, the lower substrate pads 130 for providing electrical signals may be formed on the lower surface 104 of the package substrate 100. The lower substrate pads 130 may be exposed from the lower protective layer 118. The external connection member 160 for electrical connection with an external device may be disposed on the lower substrate pad 130 of the package substrate 100. For example, the external connection member 160 may be a solder ball. The semiconductor package 10 may be mounted on a module substrate via the solder balls to form a memory module.

As mentioned above, the semiconductor package 10 may include the package substrate 100 having the receiving groove CA with the predetermined depth D from the upper surface 102, the first semiconductor chip 200 disposed within the receiving groove CA of the package substrate 100, the underfill member 300 filling the receiving groove CA of the package substrate 100 and filling a space between the first semiconductor chip 200 and an inner surface of the receiving groove CA, the plurality of second semiconductor chips 500 sequentially stacked on the first semiconductor chip 200, and the molding member 600.

The first semiconductor chip 200 may be positioned within the receiving groove CA of the package substrate 100 so as to protrude from the package substrate 100 by the predetermined height H1. The underfill member 300 may include a first covering portion 302 filling the space between the first semiconductor chip 200 and the bottom surface of the receiving groove CA. The underfill member 300 may include the third covering portion 306 that protrudes from the receiving groove CA and covers the portion of the upper surface 102 extending along the side surface of the first semiconductor chip 200 and the perimeter of the receiving groove CA.

Because a portion of the first semiconductor chip 200 used as the support structure is inserted into the receiving groove CA of the package substrate 100, a bond line thickness BLT may be reduced and the overall package thickness may be reduced. In addition, because the underfill member 300 having fluidity is formed while filling the inside of the receiving groove CA, overflow of the underfill member may be prevented, thereby reducing defects, and because there is no need to form a separate dam structure for receiving the underfill member, the degree of freedom for chip arrangement may be increased.

Hereinafter, a method of manufacturing the semiconductor package of FIG. 1 will be described according to one or more example embodiments.

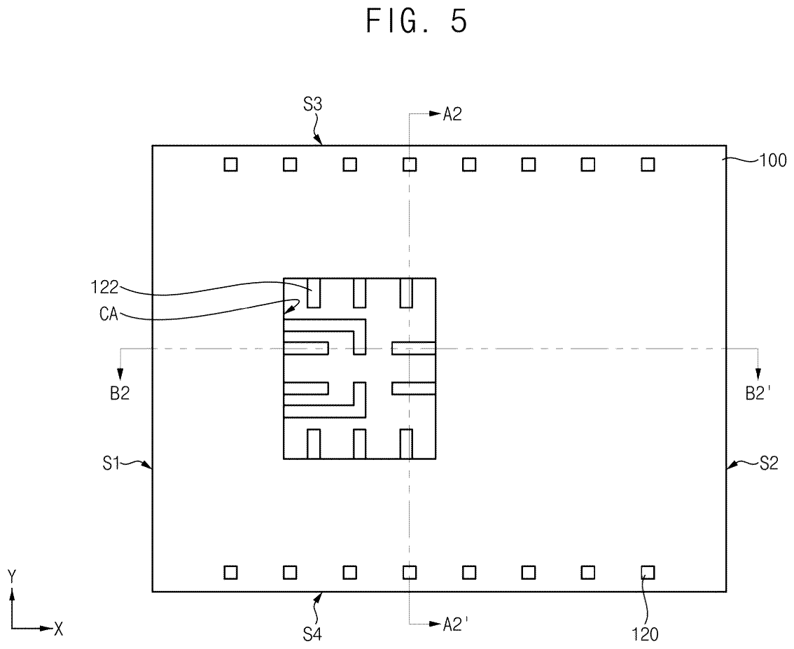

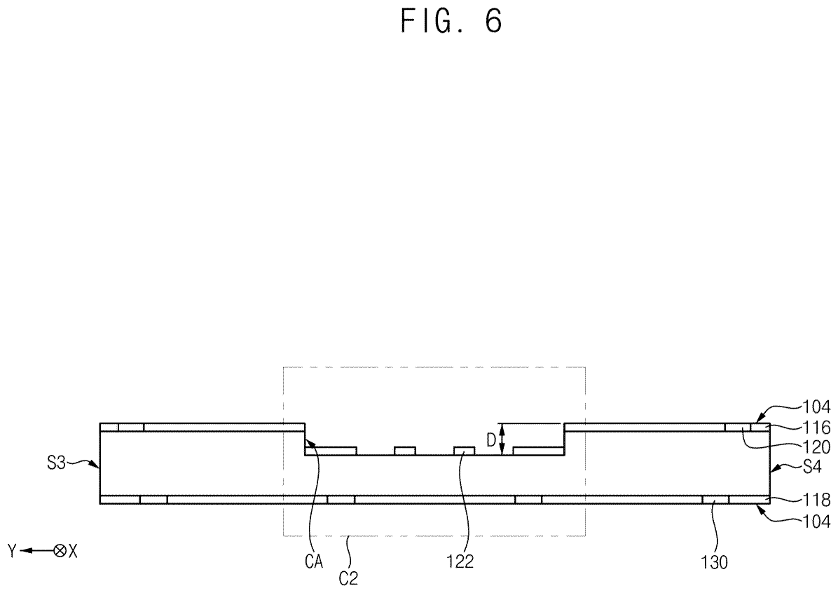

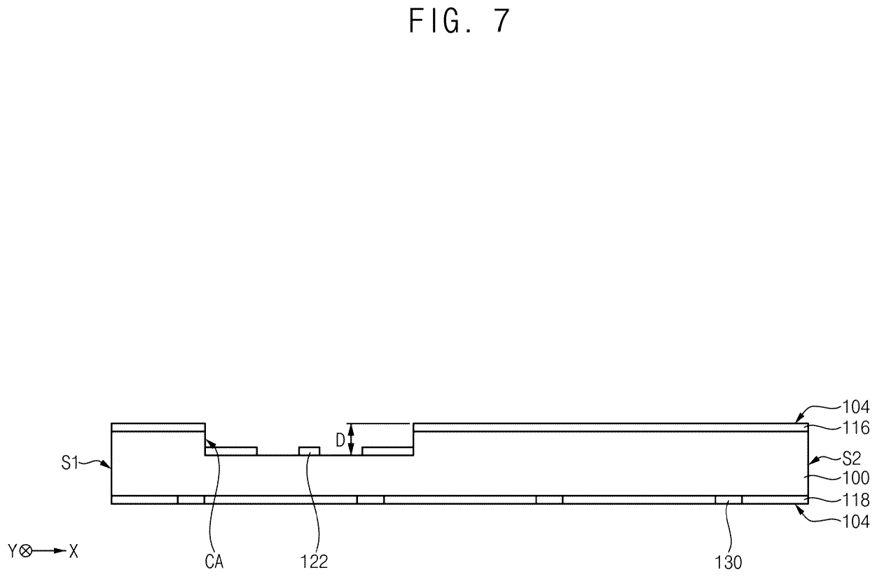

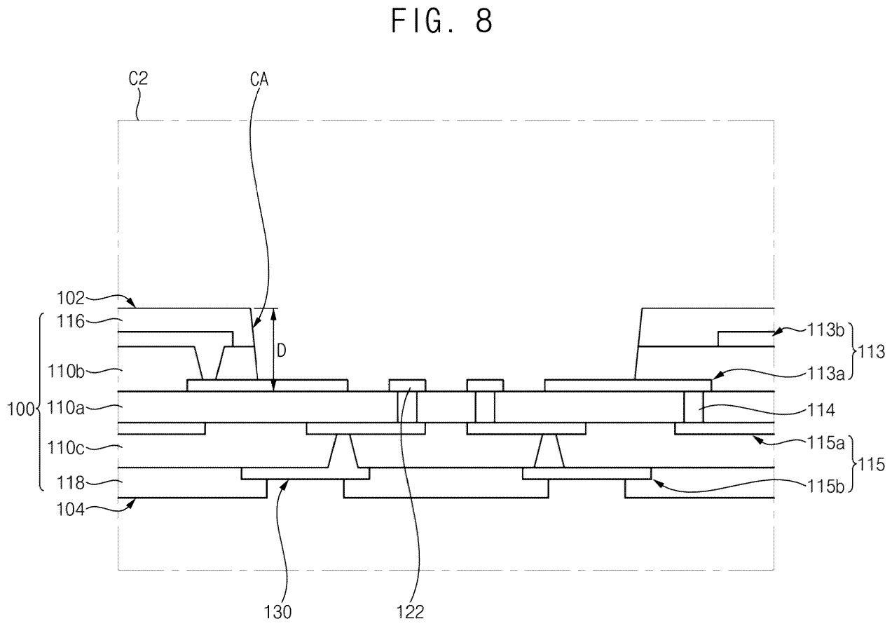

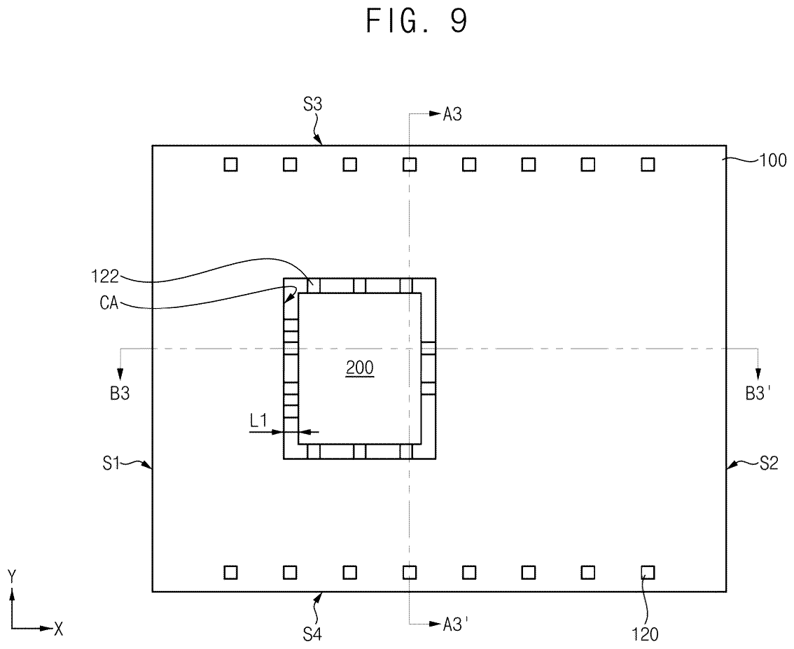

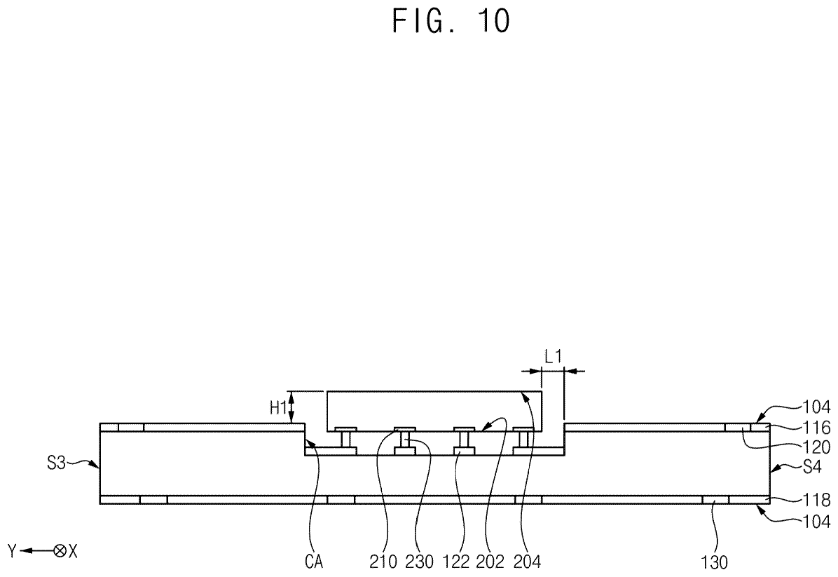

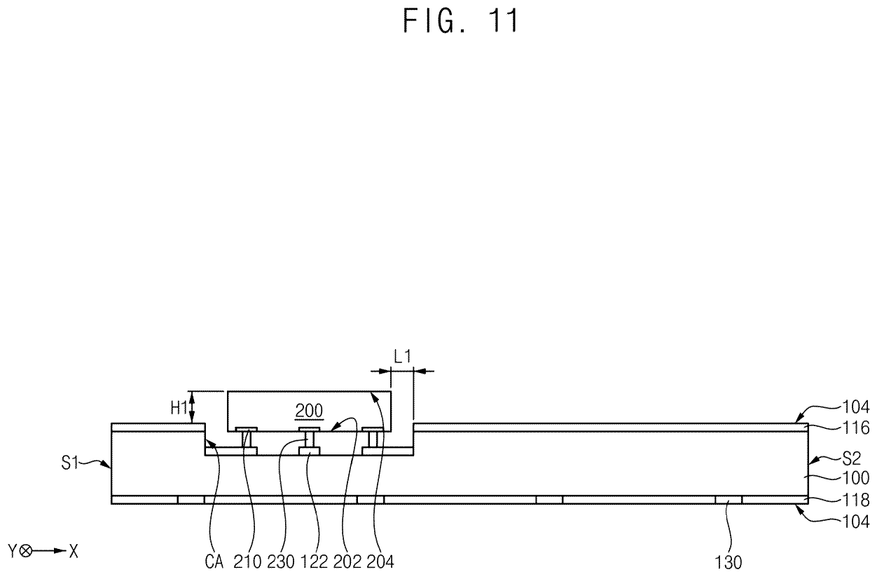

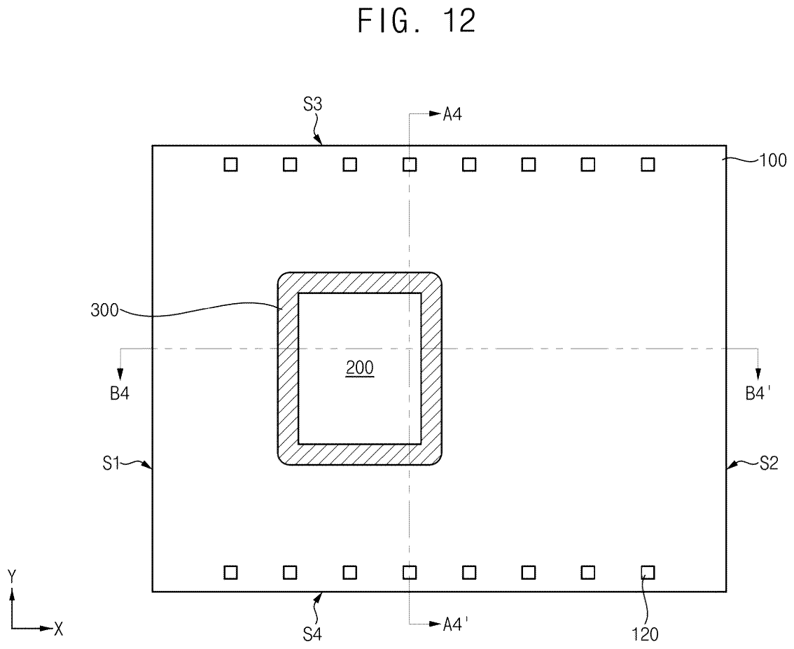

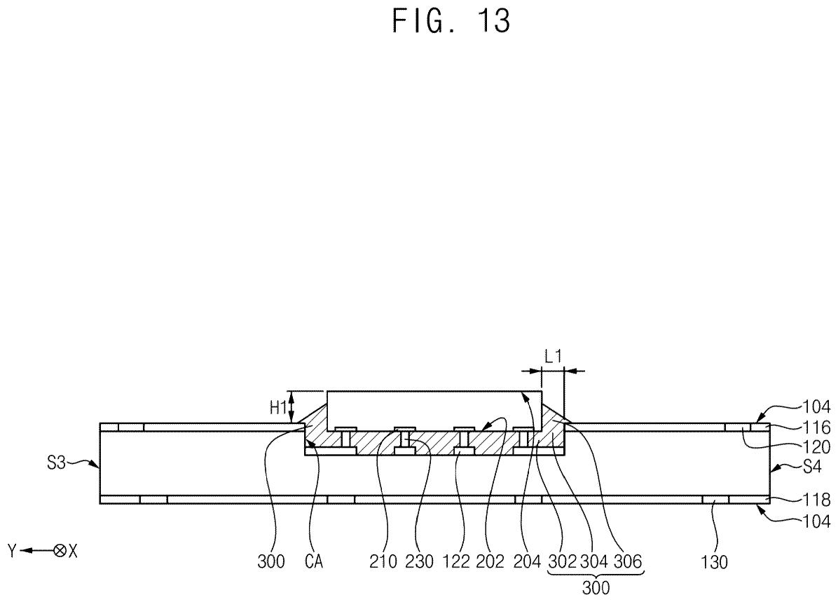

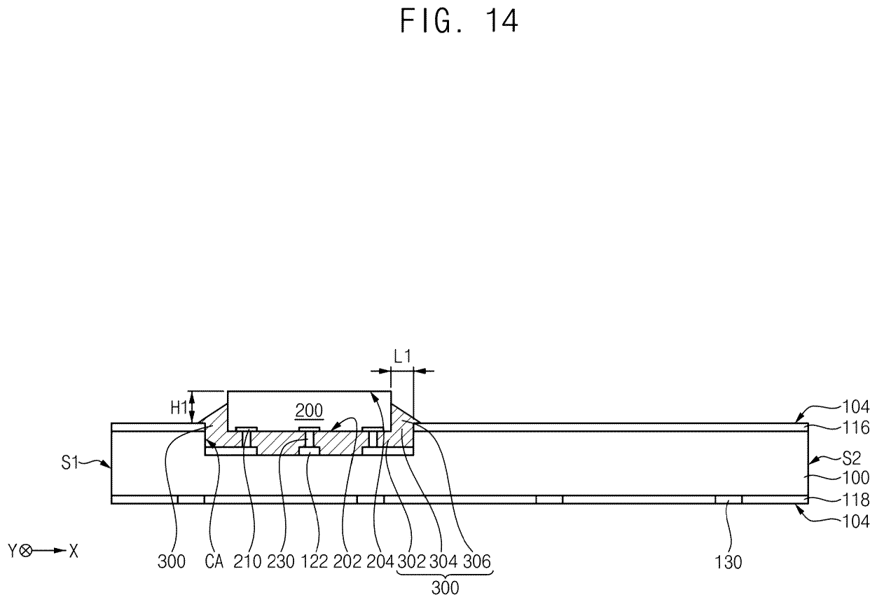

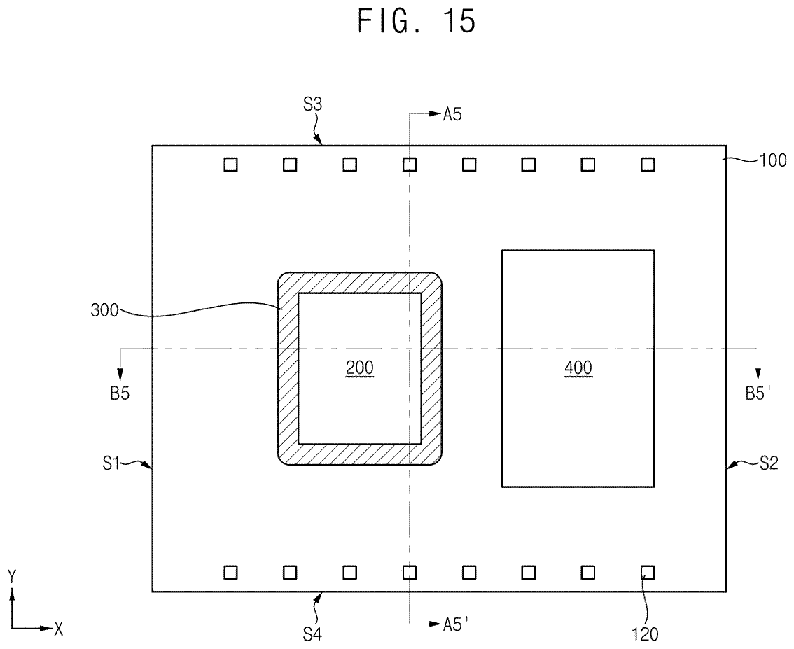

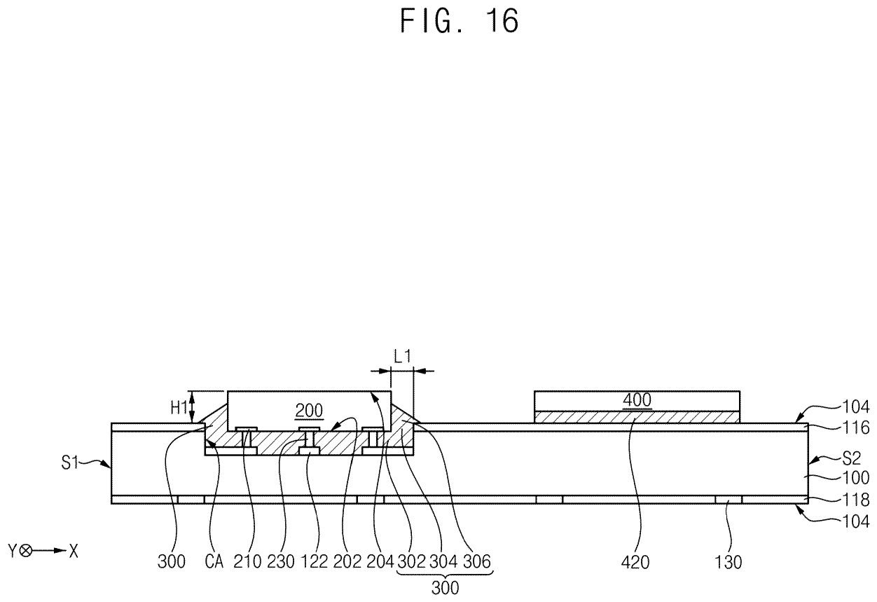

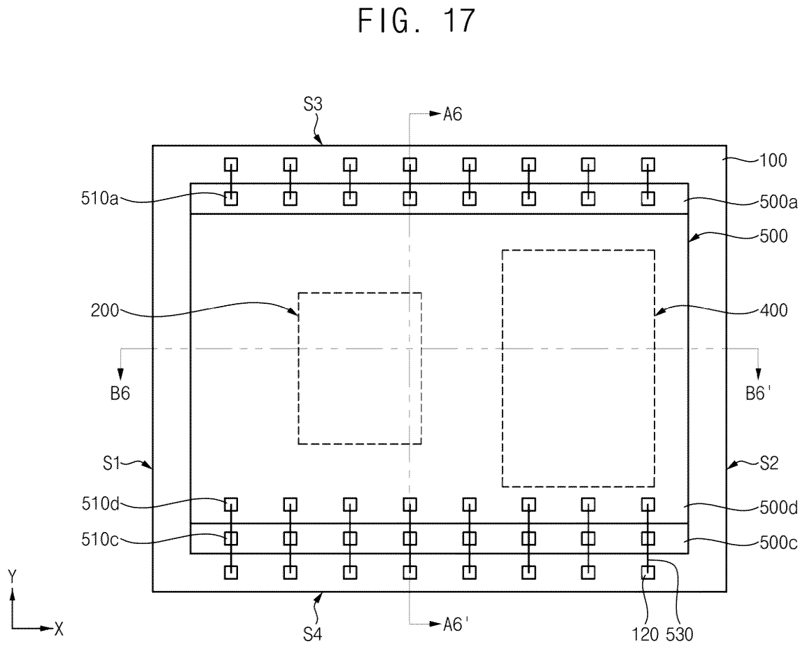

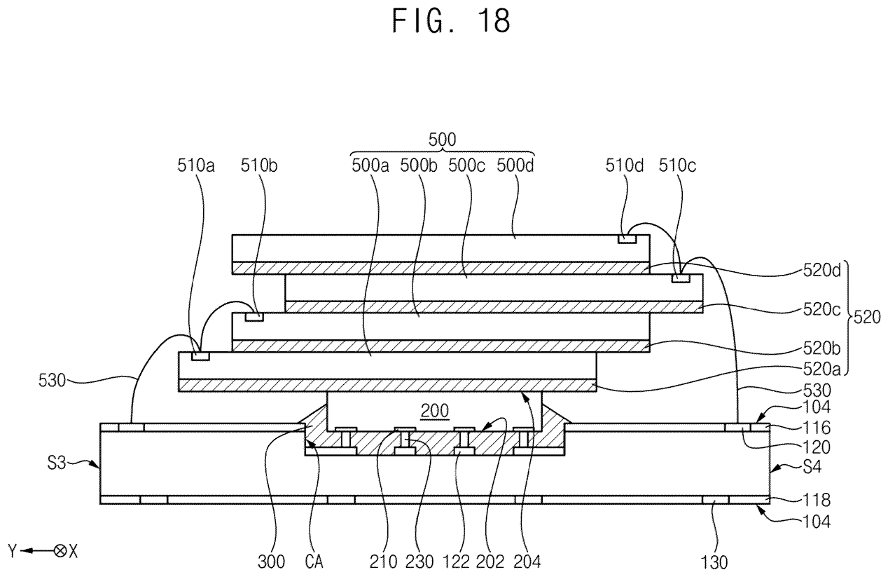

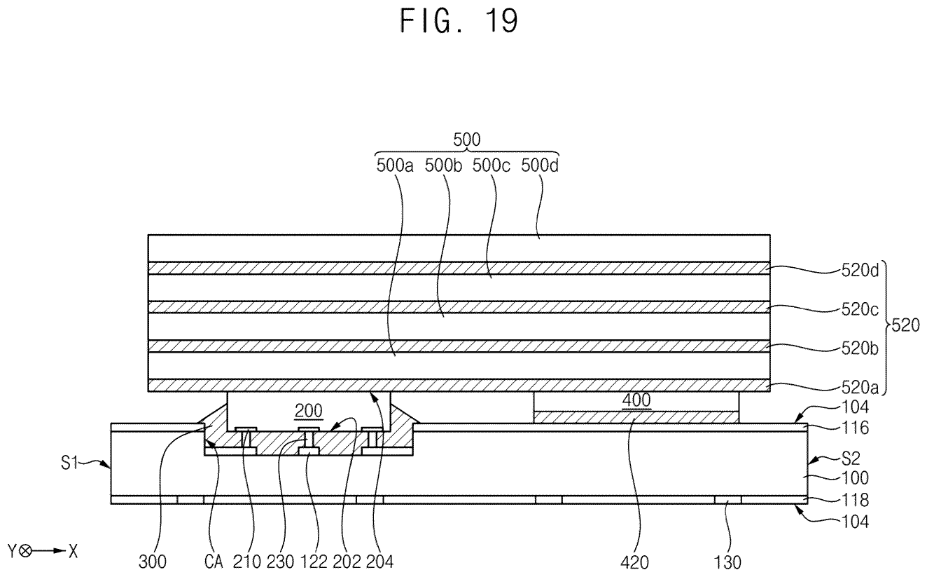

FIGS. 5, 6, 7, 8, 9, 10, 11, 12, 13, 14, 15, 16, 17, 18 and 19 are views illustrating a method of manufacturing a semiconductor package in accordance with one or more example embodiments. FIGS. 5, 9, 12, 15, and 17 are plan views illustrating a method of manufacturing a semiconductor package in accordance with one or more example embodiments. FIG. 6 is a cross-sectional view taken along the line A2-A2′ in FIG. 5, according to one or more example embodiments. FIG. 7 is a cross-sectional view taken along the line B2-B2′ in FIG. 5, according to one or more example embodiments. FIG. 8 is an enlarged cross-sectional view illustrating portion ‘C2’ in FIG. 6, according to one or more example embodiments. FIG. 10 is a cross-sectional view taken along the line A3-A3′ in FIG. 9, according to one or more example embodiments. FIG. 11 is a cross-sectional view taken along the line B3-B3′ in FIG. 9, according to one or more example embodiments. FIG. 13 is a cross-sectional view taken along the line A4-A4′ in FIG. 12, according to one or more example embodiments. FIG. 14 is a cross-sectional view taken along the line B4-B4′ in FIG. 12, according to one or more example embodiments. FIG. 16 is a cross-sectional view taken along the line B5-B5′ in FIG. 15, according to one or more example embodiments. FIG. 18 is a cross-sectional view taken along the line A6-A6′ in FIG. 17, according to one or more example embodiments. FIG. 19 is a cross-sectional view taken along the line B6-B6′ in FIG. 17, according to one or more example embodiments.

Referring to FIGS. 5, 6, 7 and 8, a package substrate 100 having at least one receiving groove CA may be provided.

As illustrated in FIGS. 5, 6 and 7, the package substrate 100 having an upper surface 102 and a lower surface 104, opposite to the upper surface 102, may be provided. The package substrate 100 may include internal wirings as channels for electrical connection with a first semiconductor chip 200 and second semiconductor chips 500 as described below.

The package substrate 100 may include a first side portion S1 and a second side portion S2 that extend in a direction parallel to a second direction (Y direction) and face each other, and a third side portion S3 and a fourth side portion S4 that extend in a direction parallel to a first direction (X direction) that is perpendicular to the second direction and face each other.

The package substrate 100 may have the receiving groove CA with a predetermined depth D from the upper surface 102. When viewed in a plan view, the receiving groove CA may have a shape corresponding to a shape of the first semiconductor chip 200. The receiving groove CA may have an approximately rectangular shape. The receiving groove CA may be arranged adjacent to the first side portion S1.

For example, the depth D of the receiving groove CA may be at least 10 μm. The depth D of the receiving groove CA may be within a range of 10 μm to 150 μm. The depth, position, planar area, etc. of the receiving groove CA may be determined in consideration of the thickness, planar area, etc. of the first semiconductor chip arranged in the receiving groove, a thickness of the underfill member, etc.

The package substrate 100 may have first substrate pads 122 for electrical connection with the first semiconductor chip 200 and second substrate pads 120 for electrical connection with the second semiconductor chips 500. The first substrate pads 122 may be provided on a bottom surface of the receiving groove CA. The first substrate pads 122 may be arranged in an array form within a chip mounting region of the receiving groove CA. The second substrate pads 120 may be provided along the third and fourth side portions (S3, S4) on the upper surface 102 of the package substrate 100. The first substrate pads 122 and the second substrate pads 120 may be connected to the wirings, respectively. The wirings may extend from the upper surface 102 or within the package substrate 100. For example, at least a portion of the wirings may be used as a landing pad by the substrate pad. Although only a few substrate pads are illustrated in the figures, it will be understood that the number, shape, and arrangement of the substrate pads are provided by way of example, and one or more example embodiments are not limited thereto.

As illustrated in FIG. 8, in one or more example embodiments, the package substrate 100 may include a core multilayer substrate. For example, the package substrate 100 may include a core layer 110a, an upper insulating layer 110b on an upper surface of the core layer 110a, and a lower insulating layer 110c on a lower surface of the core layer 110a. The package substrate 100 may further include a plurality of through vias 114 penetrating the core layer 110a, a first upper circuit layer 113a on the upper surface of the core layer 110a, a second upper circuit layer 113b provided on the upper insulating layer 110b, a first lower circuit layer 115a on the lower surface of the core layer 110a, and a second lower circuit layer 115b provided on the lower insulating layer 110c. Protective layers 116 and 118, such as solder resist layers, may be formed on outermost surfaces of the circuit layers. An upper protective layer 116 may cover the entire upper surface of the insulating layers except for the second substrate pads 120. A lower protective layer 118 may cover the entire lower surface of the insulating layers except for the lower substrate pads 130.

Each of the circuit layers may include a wiring pattern. Each of the wiring patterns may include a pad, a trace, a via, etc. An upper surface of the upper protective layer 116 may be provided as the upper surface 102 of the package substrate 100, and a lower surface of the lower protective layer 118 may be provided as the lower surface 104 of the package substrate 100. At least a portion of a pad of the second upper circuit layer 113b may be provided as the second substrate pad 120, and at least a portion of a pad of the second lower circuit layer 115b may be provided as the lower substrate pad 130.

The receiving groove CA may be formed in the package substrate 100 to have the predetermined depth D from the upper surface 102. For example, the receiving groove CA may be formed by an etching process, a laser drill process, etc. The receiving groove CA may have the predetermined depth D from the upper surface 102 of the package substrate 100 and may expose portions (e.g., pad portions) 120 of the circuit layer 113a. The exposed pad portions may be provided as the first substrate pads 122. As described below, portions of the wirings of the first upper circuit layer 113a exposed from the receiving groove CA may be pad patterns on which conductive bumps 230 formed on the first semiconductor chip 200 are respectively disposed by a flip chip bonding method. A plurality of the first substrate pads 122 may be arranged in an array form on the bottom surface of the receiving groove CA.

Referring to FIGS. 9, 10 and 11, a first semiconductor chip 200 may be mounted in the receiving groove CA of the package substrate 100. The first semiconductor chip 200 may be disposed to protrude from the upper surface 102 of the package substrate 100.

In one or more example embodiments, the first semiconductor chip 200 may be mounted in the receiving groove CA of the package substrate 100 by a flip chip bonding method. Conductive bumps 230 may be formed on the first chip pads 210 of the first semiconductor chip 200, the first semiconductor chip 200 may be disposed on a bottom of the receiving groove CA such that a front surface 202 on which the first chip pads 210 are formed faces the package substrate 100, and a reflow process may be performed to bond the conductive bumps 230 on the first substrate pads 122. The first chip pads 210 of the first semiconductor chip 200 may be electrically connected to the first substrate pads 122 of the package substrate 100 by the conductive bumps 230 as conductive connection members. For example, the conductive bumps 230 may include micro bumps (uBumps). Each of the conductive bumps 230 may include a pillar bump and a solder bump formed on the pillar bump. Alternatively, each of the conductive bumps 230 may include a solder bump.

The first semiconductor chip 200 may be a logic chip including a logic circuit. The logic chip may be a controller that controls memory chips. The first semiconductor chip 200 may be a processor chip such as an ASIC or an application processor AP as a host such as a CPU, GPU, or SOC.

For example, the first semiconductor chip 200 may have a rectangular shape with four sides when viewed in a plan view. A thickness of the first semiconductor chip 200 may be within a range of 30 μm to 100 μm. A height H1 of the first semiconductor chip 200 from the upper surface 102 of the package substrate 100 may be within a range of 30 μm to 150 μm. A distance L1 between the first semiconductor chip 200 and a sidewall of the receiving groove CA may be within a range of 40 μm to 100 μm.

The first semiconductor chip 200 may be arranged to protrude from the package substrate 100 by a predetermined height H1. The first semiconductor chip 200 may protrude from the upper surface 102 of the package substrate 100 and may be used as a support structure in a dolmen structure. The height H1 of the first semiconductor chip 200 protruding from the package substrate 100 may be determined in consideration of sizes of fillers of a molding material, a height of the second semiconductor chips 500 from the upper surface 102 of the package substrate 100, etc.

Referring to FIGS. 12, 13 and 14, an underfill member 300 may be formed in the receiving groove CA to fill a space between the first semiconductor chip 200 and an inner surface of the receiving groove CA of the package substrate 100.

For example, a liquid underfill solution may be dispensed into the receiving groove CA while moving a dispenser nozzle along the space between the first semiconductor chip 200 and a sidewall of the receiving groove CA. For example, the underfill solution may include an epoxy material. The underfill solution may flow between the first semiconductor chip 200 and the sidewall of the receiving groove CA, between the first semiconductor chip 200 and the bottom surface 112 of the receiving groove CA, and past the sidewall of the first semiconductor chip 200 onto the upper surface 102 of the package substrate 100, and may then be cured to form the underfill member 300.

The underfill member 300 may include a first covering portion 302 that fills a space between the first semiconductor chip 200 and the bottom surface of the receiving groove CA, a second covering portion 304 that fills a space between the first semiconductor chip 200 and the sidewall of the receiving groove CA, and a third covering portion 306 that covers the side surface of the first semiconductor chip 200 protruding from the receiving groove CA and a portion of the upper surface 102 extending along a perimeter of the receiving groove CA.

The third covering portion 306 may cover a portion of the side surface of the first semiconductor chip 200. The third covering portion 306 may expose an upper surface 204, i.e., a backside surface of the first semiconductor chip 200.

Referring to FIGS. 15 and 16, a support spacer 400 may be disposed on the upper surface 102 of the package substrate 100 to be spaced apart from the first semiconductor chip 200. The support spacer 400 may be attached to the upper surface 102 of the package substrate 100 by an adhesive film 420. The support spacer 400 may be disposed adjacent to the second side portion S2. The support spacer 400 may be formed by cutting a silicon wafer W by a sawing process, and then may be attached to the upper surface 102 of the package substrate 100 using the adhesive film 420 in a die attach process.

A height of the support spacer 400 from the package substrate 100 may be determined in consideration of the height H1 of the first semiconductor chip 200 protruding from the upper surface 102 of the package substrate 100. The height of the support spacer 400 from the package substrate 100 may be equal to or greater than the height H1 of the first semiconductor chip 200 from the package substrate 100.

Referring to FIGS. 17, 18 and 19, a plurality of second semiconductor chips 500 may be attached onto the first semiconductor chip 200 and the support spacer 400 using adhesive films 520.

In one or more example embodiments, a lowermost second semiconductor chip 500a may be attached onto the first semiconductor chip 200 using a first adhesive film 520a. The second semiconductor chip 500a may be attached to the first semiconductor chip 200 and the support spacer 400 using the first adhesive film 520a such as a die attach film (DAF) in a die attach process.

The second semiconductor chip 500a may be arranged such that a backside surface, i.e., an inactive surface, which is opposite to a front surface on which second chip pads 510a are formed, faces the package substrate 100. The second semiconductor chip 500a may have a rectangular shape having four sides when viewed in plan view.

For example, the first adhesive film 520a may be attached to the backside surface of the second semiconductor chip 500a, and the second semiconductor chip 500a to which the first adhesive film 520a is attached may be attached to the first semiconductor chip 200 and the support spacer 400 by a thermal compression process. The second semiconductor chip 500a may be pressed onto the first semiconductor chip 200 by a die attaching tool and may be heated to a high temperature by a heater block within a support system that supports the package substrate 100.

A portion of the DAF having fluidity due to the pressure and temperature may flow into a space between the first semiconductor chip 200 and the support spacer 400 and then may be cured.

The remaining chips 500b, 500c, 500d among a plurality of second semiconductor chips 500, may be sequentially attached to the lowermost second semiconductor chip 500a by second adhesive films 520b. The second semiconductor chips 500b, 500c, 500d may be sequentially attached to the lowermost second semiconductor chip 500a using the second adhesive films 520b such as a die attach film (DAF) in a die attach process. A thickness of each of the second adhesive films 520b may be less than a thickness of the first adhesive film 520a. The thickness of each of the second adhesive films 520b may be within a range of 10 μm to 20 μm.

A planar area of the second semiconductor chips 500 may be greater than a planar area of the first semiconductor chip 200. The plurality of second semiconductor chips 500a, 500b, 500c, 500d may be aligned to overlap each other. Alternatively, the plurality of second semiconductor chips 500a, 500b, 500c, 500d may be sequentially offset aligned from each other.

It will be understood that the number, size, arrangement, etc. of the second semiconductor chips 500 are provided as examples, and one or more example embodiments are not limited thereto. Additionally, although only a few second chip pads are illustrated in the figures, it will be understood that the structure, shapes and arrangements of the second chip pads are provided by way of example and that one or more example embodiments are not limited thereto.

The second semiconductor chips 500 may include a memory chip including a memory circuit. For example, the second semiconductor chips 500 may include volatile memory devices such as SRAM devices, DRAM devices, etc., and non-volatile memory devices such as flash memory devices, PRAM devices, MRAM devices, RRAM devices, etc. In one or more example embodiments, the second semiconductor chips 500 may include DRAM devices.

Then, the second semiconductor chips 500a, 500b, 500c, 500d may be electrically connected to the package substrate 100 by conductive connection members 530. In particular, a wire bonding process may be performed to connect the second chip pads 510a of the second semiconductor chips 500 to the second substrate pads 120 on the upper surface 102 of the package substrate 100 by bonding wires 530.

Then, a molding member (600, see FIGS. 2 and 3) may be formed on the upper surface 102 of the package substrate 100 to cover the first semiconductor chip 200, the support spacer 400, the plurality of second semiconductor chips 500, and the bonding wires 530. The molding member 600 may include a thermosetting resin, for example, an epoxy mold compound (EMC). The molding member 600 may include fillers and an epoxy resin that acts as a binder for the fillers.

Then, external connection members (160, see FIGS. 2 and 3) may be formed on the lower substrate pads 130 on the lower surface 104 of the package substrate 100, to complete the semiconductor package 10 of FIG. 1.

For example, the external connection members 160 may include solder balls. The external connection members 160 may be formed on the lower substrate pads 130 of the lower surface 104 of the package substrate 100 respectively by a solder ball attach process.

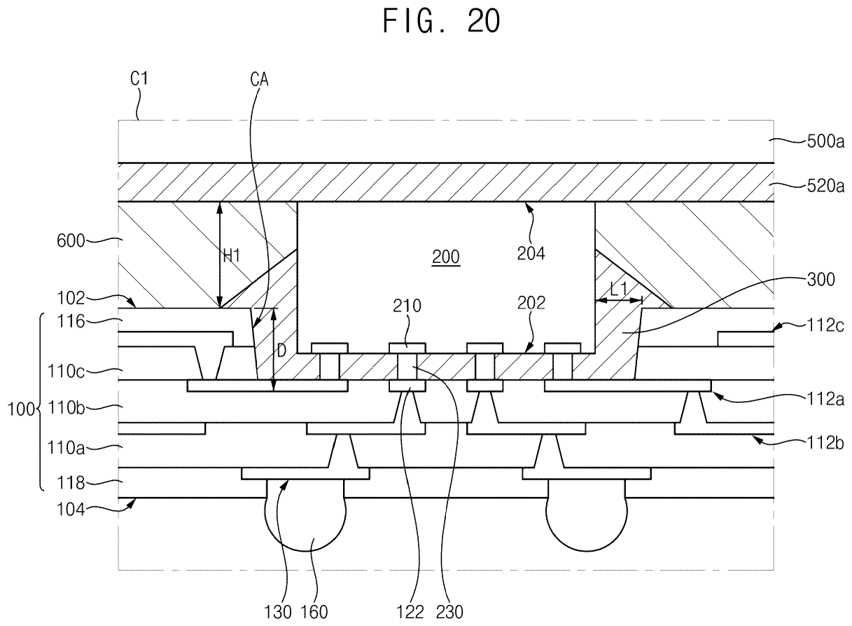

FIG. 20 is an enlarged cross-sectional view illustrating a portion of a semiconductor package in accordance with one or more example embodiments. FIG. 20 is an enlarged cross-sectional view illustrating portion ‘C1’ in FIG. 2, according to one or more example embodiments. The semiconductor package may be substantially the same as or similar to the semiconductor package described with reference to FIGS. 1, 2, 3 and 4 except for a configuration of the package substrate. Thus, same reference numerals will be used to refer to the same or like elements and any further duplicative explanation concerning the above elements will be omitted.

Referring to FIG. 20, a package substrate 100 of a semiconductor package may be a coreless substrate formed by an embedded trace substrate (ETS) method.

In one or more example embodiments, the package substrate 100 may include a core layer 110a, a plurality of insulating layers 110b and 110c, and circuit layers 112a, 112b, 112c in the insulating layers. Protective layers 116 and 118, such as solder resist layers may be formed on outermost surfaces of the circuit layers. An upper protective layer 116 may cover the entire upper surface of the insulating layers except for second substrate pads 120. A lower protective layer 118 may cover the entire lower surface of the insulating layers except for lower substrate pads 130.

Each of the circuit layers may include a wiring pattern. Each of the wiring patterns may include a pad, a trace, a via, etc. An upper surface of the upper protective layer 116 may be provided as the upper surface 102 of the package substrate 100, and a lower surface of the lower protective layer 118 may be provided as the lower surface 104 of the package substrate 100. At least a portion of the pad of an uppermost circuit layer 112c may be provided as a second substrate pad 120, and at least a portion of the pad of a lowermost circuit layer 112b may be provided as a lower substrate pad 130. It will be understood that the coreless substrate used as the package substrate is provided as an example, and one or more example embodiments are not limited thereto.

In one or more example embodiments, a receiving cavity CA may be provided to have a predetermined depth D from an upper surface 102 of the package substrate 100. For example, the receiving cavity CA may be formed by a laser drilling process. The receiving cavity CA may have a predetermined depth D from the upper surface 102 of the package substrate 100 and may expose portions (e.g., pad portions) 122 of the circuit layer 112a. The exposed pad portions may be provided as first substrate pads 122.

A first semiconductor chip 200 may be mounted on the first substrate pads 122 of the package substrate 100 via conductive bumps 230. The conductive bumps 230 may be bonded to first chip pads 210 of the first semiconductor chip 200 and the first substrate pads 122 of the package substrate 100. Accordingly, the first chip pads 210 of the first semiconductor chip 200 may be electrically connected to the first substrate pads 122 of the package substrate 100 by the conductive bumps 230 as conductive connection members.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of one or more example embodiments and is not to be construed as limiting thereof. Although one or more example embodiments have been particularly shown and described, it will be apparent to those skilled in the art that various changes in form and details may be made to one or more example embodiments without materially departing from the spirit and scope of the following claims.

What is claimed is:

1. A semiconductor package comprising:
a package substrate comprising:
an upper surface;
a lower surface opposite to the upper surface; and
a receiving groove that extends from the upper surface, toward the lower surface, by a predetermined depth;
a first semiconductor chip in the receiving groove and protruding from the upper surface of the package substrate to have a predetermined height from the upper surface of the package substrate;
an underfill member in the receiving groove and between the first semiconductor chip and an inner surface of the receiving groove;
a plurality of second semiconductor chips sequentially stacked on the first semiconductor chip; and
a molding member on the package substrate and covering the first semiconductor chip and the plurality of second semiconductor chips.

2. The semiconductor package of claim 1, wherein an upper surface of the first semiconductor chip is exposed from the underfill member.

3. The semiconductor package of claim 1, wherein the predetermined depth of the receiving groove is at least 10 μm, and
wherein the predetermined height of the first semiconductor chip from the upper surface of the package substrate is at least 30 μm.

4. The semiconductor package of claim 1, wherein the first semiconductor chip has a thickness within a range of 30 μm to 100 μm.

5. The semiconductor package of claim 1, further comprising first substrate pads on a bottom surface of the receiving groove,
wherein the first semiconductor chip comprises first chip pads on a first surface of the first semiconductor chip, and the first surface faces the package substrate, and
wherein the first semiconductor chip is mounted on the first substrate pads.

6. The semiconductor package of claim 1, wherein a lowermost second semiconductor chip, from among the plurality of second semiconductor chips, is attached to the first semiconductor chip by a first adhesive film.

7. The semiconductor package of claim 6, wherein remaining chips, from among the plurality of second semiconductor chips, are sequentially attached on the lowermost second semiconductor chip by second adhesive films.

8. The semiconductor package of claim 6, wherein the first adhesive film comprises a die attach film.

9. The semiconductor package of claim 1, further comprising:
second substrate pads on the upper surface of the package substrate; and
bonding wires electrically connecting second chip pads of the plurality of second semiconductor chips to the second substrate pads on the upper surface of the package substrate.

10. The semiconductor package of claim 1, further comprising:
a spacer chip on the package substrate and spaced apart from the first semiconductor chip,
wherein the plurality of second semiconductor chips are sequentially stacked on the spacer chip by adhesive films.

11. A semiconductor package comprising:
a package substrate comprising a receiving groove that extends from an upper surface of the package substrate, toward a lower surface of the package substrate, by a predetermined depth;
a first semiconductor chip in the receiving groove and protruding from the upper surface of the package substrate to have a first predetermined height from the upper surface of the package substrate;
at least one semiconductor element in the receiving groove of the package substrate and protruding from the upper surface of the package substrate to have a second predetermined height from the upper surface of the package substrate;
an underfill member in the receiving groove, the underfill member comprising:
a first covering portion between the first semiconductor chip and a bottom surface of the receiving groove; and
a second covering portion between the first semiconductor chip and a sidewall of the receiving groove;
a plurality of second semiconductor chips sequentially stacked on the first semiconductor chip by adhesive films; and
a molding member covering the first semiconductor chip and the plurality of second semiconductor chips,
wherein the molding member is on the package substrate, and
wherein the underfill member further comprises a third covering portion that protrudes from the receiving groove, covers a side surface of the first semiconductor chip, and covers a portion of the upper surface of the package substrate extending along a perimeter of the receiving groove.

12. The semiconductor package of claim 11, wherein an upper surface of the first semiconductor chip is exposed from the underfill member.

13. The semiconductor package of claim 11, wherein the predetermined depth of the receiving groove is at least 10 μm, and
wherein the first predetermined height of the first semiconductor chip from the upper surface of the package substrate is at least 30 μm.

14. The semiconductor package of claim 11, wherein the first semiconductor chip has a thickness within a range of 30 μm to 100 μm.

15. The semiconductor package of claim 11, further comprising first substrate pads on the bottom surface of the receiving groove,
wherein the first semiconductor chip comprises first chip pads on a first surface of the first semiconductor chip, and the first surface faces the package substrate, and
wherein the first semiconductor chip is mounted on the first substrate pads using conductive bumps that are provided on the first chip pads.

16. The semiconductor package of claim 11, wherein a lowermost second semiconductor chip from among the plurality of second semiconductor chips is attached to the first semiconductor chip by a first adhesive film from among the adhesive films, and
wherein remaining chips, from among the plurality of second semiconductor chips, are sequentially attached on the lowermost second semiconductor chip by second adhesive films from among the adhesive films.

17. The semiconductor package of claim 11, wherein the adhesive films comprise a die attach film.

18. The semiconductor package of claim 11, further comprising:
second substrate pads on the upper surface of the package substrate; and
bonding wires electrically connecting second chip pads of the plurality of second semiconductor chips to the second substrate pads.

19. The semiconductor package of claim 11, further comprising:
a spacer chip on the package substrate and spaced apart from the first semiconductor chip,
wherein the plurality of second semiconductor chips sequentially stacked on the spacer chip by adhesive films.

20. A semiconductor package comprising:
a package substrate comprising a receiving groove that extends from an upper surface of the package substrate, toward a lower surface of the package substrate, by a predetermined depth,
wherein the package substrate comprises:
first substrate pads on a bottom surface of the receiving groove; and
second substrate pads on the upper surface of the package substrate;
a first semiconductor chip in the receiving groove and protruding from the upper surface of the package substrate to have a predetermined height from the upper surface of the package substrate, wherein the first semiconductor chip is mounted on the first substrate pads using conductive bumps that are provided on first chip pads of the first semiconductor chip;
an underfill member in the receiving groove, the under fill member comprising:
a first covering portion between the first semiconductor chip and the bottom surface of the receiving groove; and
a second covering portion between the first semiconductor chip and a sidewall of the receiving groove;
a plurality of second semiconductor chips sequentially stacked on the first semiconductor chip using adhesive films, wherein the plurality of second semiconductor chips comprise second chip pads that are electrically connected to the second substrate pads by bonding wires; and
a molding member on the package substrate and covering the first semiconductor chip and the plurality of second semiconductor chips,
wherein the underfill member further comprises a third covering portion that protrudes from the receiving groove, covers a side surface of the first semiconductor chip, and covers a portion of the upper surface of the package substrate extending along a perimeter of the receiving groove.
